(19) United States
(12) Patent Application Publication
(10) Pub. No.: US 2008/0003377 A1
(43) Pub. Date: Jan. 3, 2008

(54) Transparent vacuum system

(75) Inventors: Robert A. Schill, Henderson, NV (US); Stanley R. Goldfarb, Las Vegas, NV (US); Richard A. Kant, Las Vegas, NV (US)

Correspondence Address: Mark A. Litman & Associates, P.A.;York Business Center, Suite 205, 3209 West 76th St., Edina, MN, 55435, US

(73) Assignee: The Board of Regents of the Nevada System of Higher Ed. on behalf of the UNLV

(21) Appl. No.: 11/820,360

(22) Filed: Jun. 19, 2007

Related U.S. Application Data
(60) Provisional application No. 60/818,137, filed on Jun. 30, 2006.

(51) Int. Cl. C23C 14/30

(52) U.S. Cl. 427/585; 118/50.1

(57) ABSTRACT

A vacuum chamber has a housing within which a vacuum is sustained. Various processes may be performed and electronic circuits and elements may be supported in the vacuum chamber. The housing has walls with an interior surface that comprise crosslinked polystyrene. The vacuum chamber may have interior walls that have been machined, polished etched, chemically treated, thermally treated, electromagnetic energy treated. Circuitry, electrodes and electromagnetic processes can be performed within the vacuum chamber.

### BACKGROUND OF THE INVENTION

1. Field of the Invention

The present invention relates to vacuum systems, vacuum chamber, solid wall vacuum chambers, rigid wall vacuum chambers, transparent wall vacuum chambers, resistance heated vacuum chambers, and processes using these chambers.

2. Background of the Art

Systems using vacuum chambers are well known throughout most aspects of industry, such as in: Vacuum arc vapor deposition apparatus (U.S. Pat. Nos. 6,866,753 and 5,480,527); vacuum coating and vacuum deposition (U.S. Pat. Nos. 6,830,626; 6,202,691; 6,189,806; and 6,179,923); surface treatment and workpiece treatment chambers (U.S. Pat. Nos. 6,814,838; 5,681,418; 6,783,641; and 6,703,081); vacuum plasma processing (U.S. Pat. No. 6,531,029); ionization vacuum gauges (U.S. Pat. No. 6,515,482); semiconductor lithography exposure apparatus (U.S. Pat. No. 6,510,755) and electromagnetic radiation transporting, focusing and imaging systems, as in U.S. Pat. No. 6,527,441. Examples of vacuum processing apparatuses for etching samples with plasma are disclosed in, for example, Patent Disclosure Collection 1986—official Gazette Issue No. 8153, Patent Disclosure Collection 1988—Official Gazette Issue No. 133532, Patent Disclosure Collection 1994—Official Gazette Issue No. 30369, Patent Disclosure Collection 1994—Official Gazette Issue No. 314729, Patent Disclosure Collection 1994—Official Gazette Issue No. 314730, and U.S. Pat. Nos. 5,314,509 and 5,784,799. The list of technologies and systems and processes in which vacuums are sustained during their operation is extensive.

All of these systems must have a housing or component in which the vacuum must be sustained. Originally, only metals could sustain extremely high levels of vacuum and glasses and ceramics could be used to support more moderate levels of vacuum. A significant component of the cost of these systems was the materials and construction of the housing and the components to assure that vacuums could be maintained. Polymeric substances have been used for low intensity vacuum systems, but they suffer from various problems including contamination/absorption/absorption/reaction issues by the polymer with materials or energies generated in the vacuum chamber.

Dielectric barriers such as glass, plastics, and ceramics are needed to mechanically separate two different types of environments, provide electrical isolation, and to allow for the transport of electromagnetic energy. Diffusion processes of select molecules through the wall of the barrier is usually extremely slow but becomes important when environment mediums are in direct contact with the material for a very long period of time. Once the solid medium is saturated with the environment molecules, constant outgassing of the molecule in the vacuum region results preventing one from achieving low vacuum pressures. Usually one bakes the system to remove adsorbed and absorbed molecules. But, dielectric barriers are poor thermal conductors and convection heating at moderate vacuum pressures (a few millitorr and less) becomes poor. High baking temperatures also have the effect of undesirable deforming some dielectric barriers.

Typically, Ultra High Vacuum (UHV) chambers are designed with stainless steel metal due to its low outgassing properties allowing for ultra high vacuum pressures from 10⁻⁸ to 10⁻¹¹ Torr (1.33×10⁻⁶ to 1.33×10⁻⁹ Pa) to be realized. Vacuum chambers composed of metal walls will be denoted as “standard chambers” or “standard vacuum chambers.” These standard chambers are typically opaque in the optical spectrum making it difficult to observe experiments with the naked eye except at select localized ports. Ports are required for supporting diagnostic that probe the device under test in the chamber. View ports allow for the use of external optical sources and detectors. A UHV chamber that is optically transparent may be of great utility to the researcher and the manufacturer allowing for a wider three-dimensional view of the encapsulated experiment and/or product.

The walls of standard vacuum chambers act as a reference ground to all elements internal to the chamber. With proper isolation of external peripherals, the chamber may be isolated from a common earth ground. Such isolation allows for the study of charges collected by the chamber walls. Usually this is quite hard to achieve and in some instances yields potentially dangerous floating grounds. Because the chamber may be considered as an equal potential surface on most common time scales of interest to the researcher and manufacturer, one does not have the ability to monitor localized effects on the standard vacuum chamber wall. A localized and global electrical study allow one to account for spatially distributive conservation of charge studies and affords one to monitor the cleanliness of the chamber wall through various techniques.

All of this background and each of the individual references cited are incorporated herein in its entirety for the technical disclosure therein.

### SUMMARY OF THE INVENTION

A vacuum chamber has a housing within which a vacuum is sustained. Various processes may be performed and electronic circuits and elements may be supported in the vacuum chamber, such as, but not limited to, electrical procedures, chemical procedures, physical procedures (e.g., deposition), mixed chemical and electronic procedures (such as bias-driven deposition) and the like. The housing has walls with an interior surface that comprises crosslinked polystyrene. The vacuum chamber may have interior walls that have been machined, polished etched, chemically treated, thermally treated, electromagnetic energy treated (e.g., pulsed laser, UV flash, continuously coated, deposition coated, discontinuously coated, etc.).

### BRIEF DESCRIPTION OF THE FIGURES

FIG. 1 shows a vacuum chamber having opposed electrodes within the vacuum chamber.

FIG. 2 shows a vacuum chamber with opposed electrodes in the vacuum chamber and Ohmic resistance heaters on the vacuum chamber.

### DETAILED DESCRIPTION OF THE INVENTION

A vacuum chamber has a housing within which a vacuum is sustained. The housing has walls with an interior surface that comprise crosslinked polystyrene. The vacuum chamber may have interior walls that have been machined, polished etched, chemically treated, thermally treated, electromagnetic energy treated (e.g., pulsed laser, UV flash, continuously coated, deposition coated, discontinuously coated, etc.). The polystyrene may have been crosslinked with divinylbenzene or less preferably the Zeitsev crosslinking agents such as bis-[4-(1-hydroxyethyl)phenyl]ether and its analogs. One or more electrodes may be present within the vacuum chamber and at least two electrodes can support a voltage differential within the vacuum between the at least two electrodes where at least one electrode is in the chamber. The vacuum chamber may have a system present in association with the vacuum chamber to transmit electromagnetic radiation into and/or within the vacuum chamber. The vacuum chamber may, by way of non-limiting examples support a vacuum of 0.25 Torr to 5×10⁻⁹ Torr, to 5×10⁻¹⁰ Torr or to 5×10⁻¹¹ Torr. The vacuum chamber may support an entire range of vacuum of 5×10⁻⁴ Torr to 5×10⁻⁹ Torr, to 5×10⁻¹⁰ Torr, or to 5×10⁻¹¹ Torr. The vacuum system sustaining these vacuums may have the interior surfaces with transparent Ohmic heating strips thereon. Transparent Ohmic heating strips are preferably formed by very thin metal coating, such as less than 5 microns, less than 3 microns, and even less than 1 micron, with sufficient continuity being present in the metal layer (either chemically deposited or electrically deposited). Preferred metals are aluminum, gold and platinum (because of their chemical stability), but silver, copper, brass and all other conductive metals may be used for their conductive properties.

The outgassing properties of Rexolite® polymer has been studied in an UHV environment (5×10⁻⁸ to 5×10⁻⁹ Torr). The system of the present technology can support vacuums in UHV ranges of 5×10⁻⁸ to 5×10⁻⁹ Torr, High Vacuum ranges of 5×10⁻⁷ to 5×10⁻⁸ Torr, Medium Vacuum ranges of 5×10⁻⁶ to 5×10⁻⁷ Torr, Moderate Vacuum ranges of 5×10⁻⁵ to 5×10⁻⁶ Torr, Low Moderate Vacuum ranges of 5×10⁻⁴ to 5×10⁻⁵ Torr. The system may of course be used in Low Vacuum systems of 0.2 to 0.0001 Torr. A single system can be capable of working with combinations of consecutive ranges listed above, as from 0.25 Torr to 5×10⁻⁹ Torr. Under high vacuum, the Rexolite® polymer piece is excited with both infrared and green light with intensities below the damage threshold of the plastic (less than about 100 mJ in a beam diameter of 9.5 mm and a pulse width of 5 to 7 ns). Taking care that the vacuum time constant of the chamber is long relative to the recording time of the RGA for a select number of electron/mass ratios (NOTE: A single reading may occur within an approximate 25 ms time duration.), little to no gas signature is observed. If a signature is observed, the decay rate is extremely fast on the order of less than 200 ms. Maximum partial pressure peaks of the vacuum (H₂, N₂, CH₃, O, H₂O, CO, O₂, CO₂) are monitored. Full scan studies of a typical vacuum environment containing a cleaned, polished Rexolite® polymer sample have shown for all practical purposes no adverse trace amounts of hydrocarbons. Rexolite® polymer and typical polishing compounds to condition the sample surface contain such molecules.

Rexolite® polymer may be polished to have an optical grade similar to optical lenses and view ports. This allows for using the plastic chamber in its own right as a view port allowing for three dimensional viewing of the internal contents of the chamber. The transmission properties of Rexolite® polymer exist. Experiments are currently being conducted to study the surface properties of Rexolite® polymer once polished and ground using standard grinding and polishing techniques for optics. The purpose is to minimize surface scattering and determine if bulk scattering is significant.

Unlike glass or ceramics, Rexolite® polymer is not brittle and returns back to its current shape. This is highly beneficial. Small deformations formed in materials under pressure allows for microscopic leaks when reused. These leaks will prevent the vacuum chamber from achieving UHV pressures when pumped.

Typically, migration of surface charge on plastics is a very slow process. Consequently, relatively large localized potentials may be generated changing the field properties internal to the chamber. Potentially unsafe operating and maintenance environments may result. To prevent such an effect, the internal chamber wall may be coated with a metallic film. If the metallic film is thin enough, it offers one the ability to view the inside of the chamber possibly with the aid of a light source. The metallic film is connected to wire feedthroughs leading to regions external to the chamber. Feedthroughs may then be connected to ground or external diagnostics. For example, charges lost to the walls of the vacuum may now be controllably monitored without taking special grounding and isolation precautions. Thin films may be sectored or configured in such a manner to use the vacuum chamber as a diagnostic tool using the capacitive, inductive and resistive properties of the chamber as a whole. Using the plastic as a support, semiconductor materials may be attached to the inside walls of the vacuum chamber for numerous diagnostic measurements. With thin film sectoring, uniformity processes may be studied. Both electric and magnetic fields may be introduced into the chamber with external voltage and/or current sources. By changing the film wall thickness (e.g., a graded or uniform thickness), the transmission properties of the optical radiation may be somewhat controlled. (NOTE: Sun glasses with a metallic thin film are available on the market.) Although not exhaustively examined, it is well known that radiation damaged fiber optics (UV, X-ray etc.) typically turn opaque preventing the transmission of light. Consequently, one has a passive means to monitor the ionization radiation internal to the chamber in a vacuum environment. Optically damaged fibers tend to self heal when the radiation source is removed. Metallic films may be used as a means to study high field emission in localized regions. Thin films may be used as a waveguide structure to transport electromagnetic energy. Numerous slow wave and fast wave structures with isolation may be designed in a vacuum environment. (Coating placement, thickness, and geometry determines the type of structure designed.) It is thus possible to use the highly crosslinked polystyrene of the present technology in vacuum optical fiber technology, as the optical fiber interior. Depending on the wall thickness and skin depth properties of the metal, high frequency waves may resonate in the vacuum chamber while low frequency electromagnetic waves may tunnel through the plastic/metal structure. One of the advantages of the Rexolite® polymer vacuum chamber with thin films is weight. For equal volume of material, Rexolite® polymer is much lighter than stainless steel. If one may maintain operating temperatures lower than the crazing temperature of the plastic, the concept may be extended to a whole new generation of high power microwave vacuum tubes potentially of interest to the Department of Defense (DOD). Lightweight, lower manufacturing costs with potential external monitoring capabilities are attractive. Because Rexolite® polymer may have an elastic memory, interferometry techniques may be used as a diagnostic to monitor stress/strain properties of the material in real time. Material fatigue studies and acoustic wave studies supported by the material provide useful information regarding system vibrations.

Stainless steel is a fair thermal conductor. Heating the inside chamber wall using external heating mechanisms placed on the outside of the vessel takes time and energy. Without an internal atmosphere, conduction heating is not usually uniform. Heating a Rexolite® polymer chamber with thin film may be performed in a couple of unique ways. RF heating may be performed using a Faraday induction effect. This technique requires no electrical contact. A second technique is to use Ohmic heating by applying a voltage source to the feedthrough leading to the internal thin film strips on the inside wall of the chamber. The strips would have to be designed in such a manner to provide somewhat uniform heating. Baking the Rexolite® polymer vacuum chamber will be substantially decreased compared to that of standard vacuum chambers. Baking temperatures below the crazing temperature of 114° C. need to be maintained in order to avoid heat stressing the plastic proper.

Rexolite® polymer is a cross-linked polystyrene manufactured by C-Lec Corporation under the brand name Rexolite®. The polymer is quite useful in the practice of the present technology. The polystyrene has an ultrasonic impedance of approximately 2.6 and a dielectric constant of 2.53. Rexolite® polymer is a unique cross-linked polystyrene, microwave plastic, using divinylbenzene as the crosslinking agent. Other crosslinking agents for polystyrene are disclosed and enabled in U.S. Pat. No. 6,143,922 (Zeitsev). Materials such as bis-[4-(1-hydroxyethyl)phenyl]ether (referred to as BHEPE) are described The Zeitsev reference is incorporated by reference for the teaching of additional polystyrene crosslinking agents and all crosslinked products. This material's most notable properties are it's unusually stable electrical properties into the Giga-hertz frequency range. It is also optically clear (approximately the same as Acrylic), dimensionally stable, and excellent sound transmission characteristics.

As a result, Rexolite® polymer is often used for high-frequency circuit substrates, microwave components, and lenses with acoustic, optical and radio-frequency applications.

Rexolite® Polymer Grades

### Rexolite® 1422 POLYMER—unfilled

Unfilled Rexolite® 1422 polymer is chemically resistant, light weight, resists water absorption, and has negligible outgassing.

### Rexolite® 2200 Polymer—Glass-Filled

Glass reinforced Rexolite® polymer 2200 provides greater rigidity and dimensional stability while maintaining many of the useful characteristics of basic Rexolite® polymer. The glass reinforcement yields a product with an exceptional strength-to-weight ratio and increased tensile strength.

Rexolite® Polymer Copper-Clad

This polymer may be particularly used in electronic circuits, both Rexolite® polymer 1422 and 2200 may be ordered in sheet thicknesses to ¼″ with copper-clad surface in thicknesses ranging from ½-ounce to 2-ounce copper.

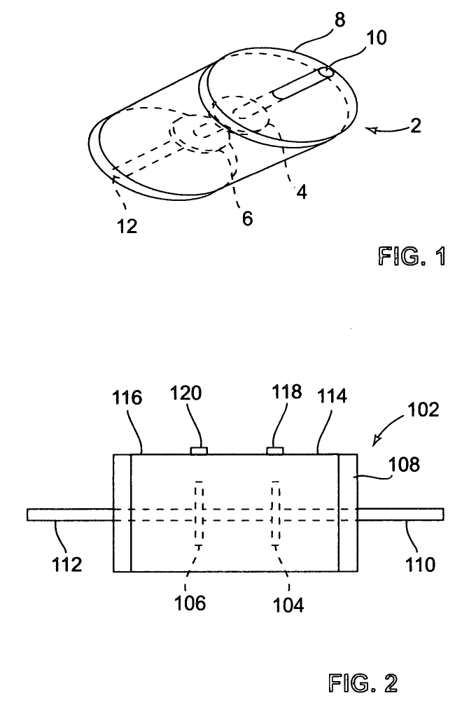

FIG. 1 shows a vacuum chamber 2 having opposed electrodes 4 6 within the vacuum chamber 2. The walls 8 of the vacuum chamber 2 are made of transparent crosslinked polystyrene (specifically Rexolite® resin was used) and the two opposed electrodes 4 6 have external leads 10 12 associated therewith.

FIG. 2 shows a vacuum chamber 102 with two opposed electrodes 104 106 within the walls 108 of the vacuum chamber 102. There are two connectors (e.g., wires or cables) 110 112 on the electrodes 104 106. Two separate Ohmic resistance heating elements 114 116 are shown on the vacuum chamber 102 with two connectors 118 120 (e.g., wires or cables) fopr the Ohmic heating elements 114 116. Alternatively, the Ohmic heating elements 114 116 could be replaced by cooling elements (e.g., Peltier systems) or light emitting diodes or semiconductors or field affecting circuitry on the exterior of the walls 108. In the system shown in FIG. 2, the Ohmic resistance heating elements 114 116 are transparent, as preferably would be any other systems associated with the external or internal surfaces of the walls 108.

Among the benefits of the system are at least the relatively low manufacturing costs for a high efficiency, relatively durable electrical or electronic vacuum system, a readily reproducible electronic or electrical systems, an electronic or electrical systems that can be made by conventional and efficient manufacturing processes, and an electronic or electrical system that can be used with known structures and designs for existing electronic or electrical systems with only a change in material content for the housing. The unique capability of a housing material that allows for support of a stable vacuum and transparency, without the fragility of a glass system is also an important commercial and technical consideration. The use of polymeric compositions also allows for facility in molding and shaping the articles, and the touch crosslinked compositions of this technology allows for machining and ready post-working of the article.

The technology described herein may be generally summarized as including a vacuum chamber having a housing within which housing a vacuum is sustained, the housing having walls with an interior surface that comprise crosslinked polystyrene. The interior walls may have been machined. The polystyrene may be crosslinked with divinylbenzene or a bis-[4-(1-hydroxyethyl)phenyl]ether. At least one electrode may be present within the vacuum chamber and the at least two electrodes may support a voltage differential between the at least two electrodes where at least one electrode is in the chamber. In the vacuum chamber, a system may be present in association with the vacuum chamber to transmit electromagnetic radiation within and through the vacuum chamber. In one non-limiting embodiment, the vacuum chamber can support a vacuum at least within the range of 0.25 Torr to 5×10⁻⁹ Torr and the walls are transparent, or for example a vacuum of 5×10⁴ Torr to 5×10⁻⁹ Torr and the walls are transparent. The vacuum system omay also be manufactured with the interior surfaces or the exterior surfaces having transparent Ohmic heating strips thereon. The vacuum system may be provided with transparent vacuum chamber walls supporting partial or total coverage of a metallic coating used as an internal diagnostic or as an isolated grounding.

A method of using the vacuum system described herein may include, with transparent vacuum chamber walls supporting a partial or total coverage of metallic coating, interacting with internal beams selected from the group consisting of electromagnetic radiation beams and electron beams for generating electromagnetic energy in a different form or for electronic purposes, the method comprising directing the internal beam through the vacuum within the vacuum system, the beam emanating from or impacting at least one electrode within the vacuum. This type of method using the vacuum system with transparent vacuum chamber walls that support partial or total coverage of metallic coating for interacting with internal electromagnetic radiation beams or electron beams comprising directing the internal beam through the vacuum within the vacuum system, the beam emanating from or impacting at least one electrode within the vacuum to accelerate or decelerate charged particle beams.

What is claimed:

1. A vacuum chamber having a housing within which housing a vacuum is sustained, the housing having walls with an interior surface that comprise crosslinked polystyrene.

2. The vacuum chamber of claim 1 wherein the interior walls have been machined.

3. The vacuum chamber of claim 1 wherein the polystyrene has been crosslinked with divinylbenzene.

4. The vacuum chamber of claim 1 wherein the polystyrene has been crosslinked with bis-[4-(1-hydroxyethyl)phenyl]ether.

5. The vacuum chamber of claim 2 wherein the polystyrene has been crosslinked with divinylbenzene.

6. The vacuum chamber of claim 2 wherein the polystyrene has been crosslinked with bis-[4-(1-hydroxyethyl)phenyl]ether.

7. The vacuum chamber of claim 1 wherein at least one electrode is present within the vacuum chamber and the at least two electrodes can support a voltage differential between the at least two electrodes where at least one electrode is in the chamber.

8. The vacuum chamber of claim 2 wherein at least one electrode is present within the vacuum chamber and the at least two electrodes can support a voltage differential between the at least two electrodes where at least one electrode is in the chamber.

9. The vacuum chamber of claim 1 wherein a system is present in association with the vacuum chamber to transmit electromagnetic radiation within and through the vacuum chamber.

10. The vacuum chamber of claim 2 wherein a system is present in association with the vacuum chamber to transmit electromagnetic radiation within and through the vacuum chamber.

11. The vacuum chamber of claim 1 supporting a vacuum of 0.25 Torr to 5×10⁻⁹ Torr and the walls are transparent.

12. The vacuum chamber of claim 1 supporting a vacuum of 5×10⁻⁴ Torr to 5×10⁻⁹ Torr and the walls are transparent.

13. The vacuum system of claim 1 wherein the interior surfaces have transparent Ohmic heating strips thereon.

14. The vacuum system of claim 7 wherein the interior surfaces have transparent Ohmic heating strips thereon.

15. The vacuum system of claim 1 with transparent vacuum chamber walls supporting partial or total coverage of a metallic coating used as an internal diagnostic or as an isolated grounding.

16. A method of using the vacuum system of claim 1 with transparent vacuum chamber walls supporting a partial or total coverage of metallic coating for interacting with internal beams selected from the group consisting of electromagnetic radiation beams and electron beams for generation of electromagnetic energy in a different form or for electronic purposes comprising directing the internal beam through the vacuum within the vacuum system, the beam emanating from or impacting at least one electrode within the vacuum.

17. A method of using the vacuum system of claim 1 with transparent vacuum chamber walls support partial or total coverage of metallic coating for interacting with internal electromagnetic radiation beams or electron beams comprising directing the internal beam through the vacuum within the vacuum system, the beam emanating from or impacting at least one electrode within the vacuum to accelerate or decelerate charged particle beams.
